(19) United States
(12) Patent Application Publication
(10) Pub. No.: US 2025/0294989 A1
(43) Pub. Date: Sep. 18, 2025

(54) MULTIFACETED DISPLAY DEVICE AND DISPLAY APPARATUS

(71) Applicant: c/o Sharp Display Technology Corporation, Kameyama City, Mie (JP)

(72) Inventors: Kyohei WAKATSUKI, Kameyama City, Mie (JP); Sadao SAKAMOTO, Kameyama City, Mie (JP)

(21) Appl. No.: 18/859,253

(22) PCT Filed: Jun. 14, 2022
(86) PCT No.: PCT/JP2022/023714

§ 371 Date: Oct. 23, 2024

(51) Int. Cl. H10K 59/18; H10K 102/00

(52) U.S. Cl. CPC H10K 59/18; H10K 2102/311

(57) ABSTRACT

A multi-surface display device includes a first display panel configured to perform display toward a first direction, a second display panel configured to perform display toward a second direction different from the first direction, and a third display panel that is foldable and connected to the first display panel and the second display panel and configured to perform display toward a third direction different from the first and second directions. The third display panel is switched between a use state in a flat plate shape and a storage state in which the third display panel is folded, and the first display panel and the second display panel are closer to each other than in the use state.

### TECHNICAL FIELD

The disclosure relates to a multi-surface display device and a display device.

### BACKGROUND ART

There is known a display device in which a plurality of display plates having a flat plate shape are used and the display plates are arranged to form a polygon as a display portion (PTL 1).

Further, there is known a display device that includes a flexible display having a foldable configuration (PTL 2).

### CITATION LIST

### Patent Literature

PTL 1: JP 61-65490 UM-A

PTL 2: JP 2021-179804 A

### SUMMARY

### Technical Problem

The display device described in PTL 1 is inconvenient for storage when not in use since the volume of a display portion arranged to form a polygon is large.

The display device described in PTL 2 only discloses a state in which a flexible display is closed to be in a layered form and a state in which the flexible display is opened to be in a flat plate form, and PTL 2 does not disclose or suggest arranging the flexible display so as to form a polygon.

### Solution to Problem

A multi-surface display device according to an aspect of the disclosure includes a first display panel configured to perform display toward a first direction, a second display panel configured to perform display toward a second direction different from the first direction, and a third display panel that is foldable and connected to the first display panel and the second display panel and configured to perform display toward a third direction different from the first and second directions. The third display panel is switched between a use state in a flat plate shape and a storage state in which the third display panel is folded such that the first display panel and the second display panel are closer to each other than in the use state.

A display device according to an aspect of the disclosure includes a first plate- shaped member, a second plate-shaped member connected to the first plate-shaped member, and a display panel connected to the first plate-shaped member and the second plate-shaped member and configured to be foldable. The display panel is switched between a use state in a flat plate shape and a storage state in which the display panel is folded such that the first plate-shaped member and the second plate-shaped member are closer to each other than in the use state.

### Advantageous Effects of Disclosure

According to an aspect of the disclosure, it is possible to provide a multi-surface display device and a display device in which storage when not in use is facilitated.

### BRIEF DESCRIPTION OF DRAWINGS

FIG. 1 is a perspective view of a multi-surface display device according to a first embodiment.

FIG. 2 is a plan view of the multi-surface display device.

FIG. 3 is a plan view illustrating a storage operation of the multi-surface display device.

FIG. 4 is a plan view illustrating a storage operation of the multi-surface display device.

FIG. 5 is a plan view illustrating a storage operation of the multi-surface display device.

FIG. 6 is a plan view of a display device according to a comparative example.

FIG. 7 is a perspective view of the multi-surface display device according to a modified example.

FIG. 8 is a plan view of the multi-surface display device according to the modified example.

FIG. 9 is a plan view illustrating a storage operation of the multi-surface display device according to the modified example.

FIG. 10 is a plan view illustrating a storage operation of the multi-surface display device according to another modified example.

FIG. 11 is a plan view illustrating a storage operation of the multi-surface display device according to another modified example.

FIG. 12 is a plan view of the multi-surface display device according to further another modified example.

FIG. 13 is a front view of the multi-surface display device according to further another modified example.

FIG. 14 is a plan view illustrating a storage operation of the multi-surface display device according to further another modified example.

FIG. 15 is a plan view of a multi-surface display device according to a second embodiment.

FIG. 16 is a plan view illustrating a storage operation of the multi-surface display device.

FIG. 17 is a schematic view of a display device according to a third embodiment.

FIG. 18 is a schematic view illustrating a storage operation of the display device.

### DESCRIPTION OF EMBODIMENTS

### First Embodiment

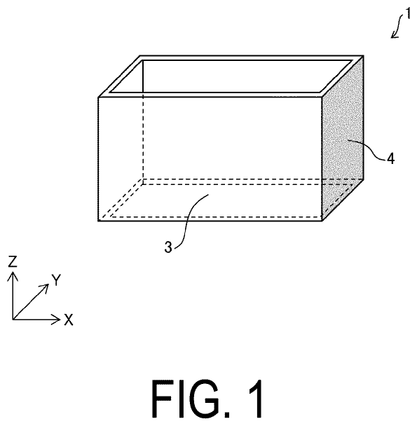

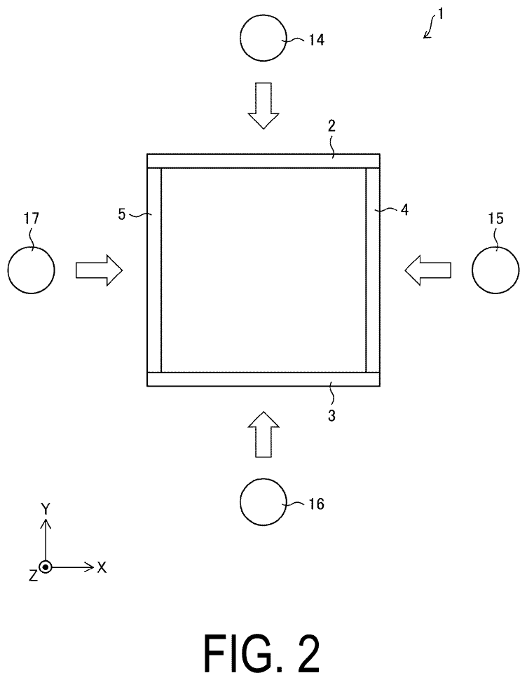

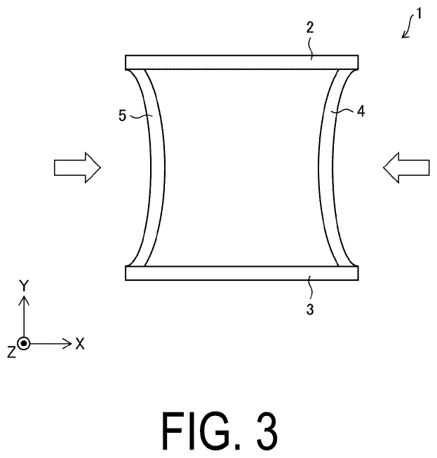

FIG. 1 is a perspective view of a multi-surface display device 1 according to a first embodiment. FIG. 2 is a plan view of the multi-surface display device 1. FIGS. 3 to 5 are plan views each illustrating a storage operation of the multi-surface display device 1.

The multi-surface display device 1 includes a first display panel 2 that performs display toward a Y direction (first direction), a second display panel 3 that performs display toward a-Y direction (second direction), and a third display panel 4 that is foldable and connected to the first display panel 2 and the second display panel 3 to perform display toward an X direction (third direction). The third display panel 4 is switched between a use state in a flat plate shape illustrated in FIGS. 1 and 2 and a storage state in which the third display panel 4 is folded such that the first display panel 2 and the second display panel 3 are closer to each other than in the use state as illustrated in FIGS. 3 to 5.

Thus, in the storage state of the multi-surface display device 1, the third display panel 4 is folded, and the first display panel 2 and the second display panel 3 are closer to each other than in the use state. Thus, the multi-surface display device 1 in the storage state becomes more compact than in the use state. As a result, there is an exceptionally remarkable effect of facilitating the storage when not in use of the multi-surface display device 1.

The multi-surface display device 1 preferably further includes a fourth display panel 5 that is foldable and connected to the first display panel 2 and the second display panel 3 to perform display toward a −X direction (fourth direction). The fourth display panel 5 has a flat plate shape in the use state and is folded such that the first display panel 2 and the second display panel 3 are closer to each other in the storage state than in the use state. In the use state, the first, second, third, and fourth display panels 2, 3, 4, and 5 are arranged in a quadrangular shape as illustrated in FIGS. 1 and 2. As illustrated in FIGS. 3 to 5, the third and fourth display panels 4 and 5 are folded so as to protrude inward in the storage state.

Thus, in the storage state of the multi-surface display device 1 in which the first, second, third, and fourth display panels 2, 3, 4, and 5 are arranged in a box-like quadrangular shape in the use state, the third display panel 4 and the fourth display panel 5 are folded so as to protrude inward, and the first display panel 2 and the second display panel 3 are closer to each other than in the use state. Thus, the multi-surface display device 1 in which the first, second, third, and fourth display panels 2, 3, 4, and 5 are arranged in the quadrangular shape in the use state becomes compact in the storage state. As a result, the storage when not in use of the multi-surface display device 1 arranged in the quadrangular shape is facilitated.

The first and second display panels 2 and 3 preferably have the foldable configuration. The first, second, third, and fourth display panels 2, 3, 4, and 5 are preferably integrally formed. That is, the first, second, third, and fourth display panels 2, 3, 4, and 5 are preferably formed by bending a single display panel. For example, a pixel circuit layer and a light-emitting element layer of the first display panel 2, a pixel circuit layer and a light-emitting element layer of the second display panel 3, a pixel circuit layer and a light-emitting element layer of the third display panel 4, and a pixel circuit layer and a light-emitting element layer of the fourth display panel 5 may be formed on the same flexible substrate with a gap therebetween. This gap does not include a pixel circuit layer or the like, and thus is suitable as a bending portion between the display panels. A material having a high shape memory property may be used for the flexible substrate. The light-emitting element layer may include a light-emitting element such as an OLED, and the pixel circuit layer may include a pixel circuit that controls the light- emitting element. A control board (IC board) may be provided on a back surface (surface opposite to a display surface) of each of the first to fourth display panels 2 to 5. Any one of the control boards may be set as a master, and the others may be set as slaves.

Third display panel 4 and fourth display panel 5 may be provided with a bending portion in a display region. In the bending portion in the display region, an inorganic insulating film (silicon nitride, silicon oxide, or the like) of the pixel circuit layer may be removed and a recessed portion formed by the removal may be filled with an organic layer such as a resin, so that flexibility may be increased. From the viewpoint of flexibility and prevention of disconnection, a wiring line extending across the bending portion may include aluminum, may have a layered structure, or may have a redundant structure (double wiring line with an insulating layer interposed therebetween or the like). A light-emitting element located at the bending portion in the display region can be controlled by a pixel circuit formed adjacent to the bending portion. A resolution (density of light-emitting elements) may be reduced in the bending portion.

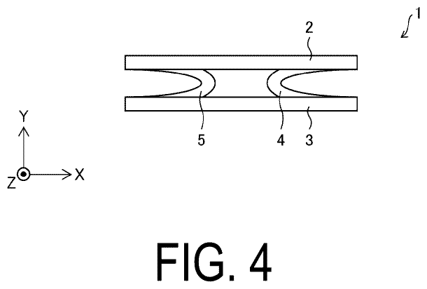

As illustrated in FIGS. 1 and 2, in the use state, a portion between the first display panel 2 and the third display panel 4 is preferably bent at a right angle, and a portion between the first display panel 2 and the fourth display panel 5 is preferably bent at a right angle. As illustrated in FIGS. 3 and 4, in the storage state, a portion between the first display panel 2 and the third display panel 4 is preferably bent at an acute angle, and a portion between the first display panel 2 and the fourth display panel 5 is preferably bent at an acute angle.

According to this configuration, with the simple configuration in which the first, second, third, and fourth display panels 2, 3, 4, and 5 are integrally formed, in the storage state of the multi-surface display device 1 arranged in the quadrangular shape, the third display panel 4 and the fourth display panel 5 are folded so as to protrude inward, and the first display panel 2 and the second display panel 3 are closer to each other than in the use state.

The first, second, and third display panels 2, 3, and 4 preferably, include an organic light-emitting diode (OLED).

The multi-surface display device 1 can be applied to an OLED panel which is very thin and effective even in bending. Note that the display panel may be a liquid crystal display.

A metal thin plate having a mesh shape is preferably attached to the third display panel 4.

The metal thin plate having a mesh shape can be made of, for example, stainless steel.

Thus, the third display panel 4 that is foldable and thin can maintain its posture by itself.

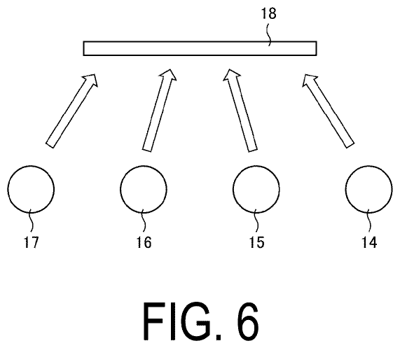

FIG. 6 is a plan view of a display device according to a comparative example.

For example, in order to play a video game by four users 14, 15, 16, and 17, the users 14, 15, 16, and 17 each view a display panel 18 of a monitor at angles inclined with respect to the display panel 18 as illustrated in FIG. 6.

In order to solve the problem and cause each of the users 14, 15, 16, and 17 to exclusively view the display panel 18 from the front, the multi-surface display device 1 of a four-surface display illustrated in FIGS. 1 and 2 is provided. Since such a multi- surface display device 1 is bulky when stored, as illustrated in FIGS. 3 to 5, the third and fourth display panels 4 and 5 facing each other are of a folding type taking advantage of the characteristics of the flexible panel.

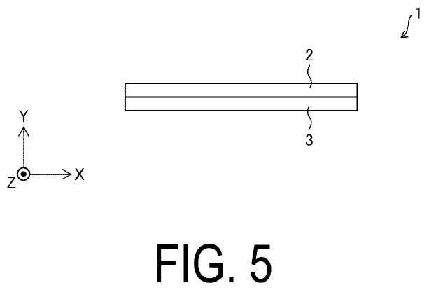

When the multi-surface display device 1 is stored, first, as illustrated in FIG. 3, a force in the −X direction is applied to the third display panel 4 in the use state in the flat plate shape, and a force in the X direction is applied to the fourth display panel 5 in the use state in the flat plate shape. Then, the third display panel 4 and the fourth display panel 5 both start to be curved inward as illustrated in FIG. 3. As illustrated in FIGS. 2 to 4, the first display panel 2 and the second display panel 3 are closer to each other than in the use state. Thereafter, third display panel 4 and fourth display panel 5 are further curved, and the first display panel 2 and the second display panel 3 are further brought closer to each other and come into contact with each other. Thus, as illustrated in FIG. 5, the multi-surface display device 1 in the storage state has a compact size corresponding to two display panels.

The example has been described in which the third display panel 4 and the fourth display panel 5 are folded so as to protrude inward. However, no such limitation is intended, and the third display panel 4 and the fourth display panel 5 may be folded so as to protrude outward.

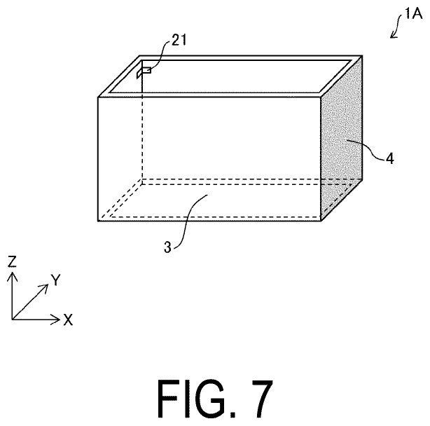

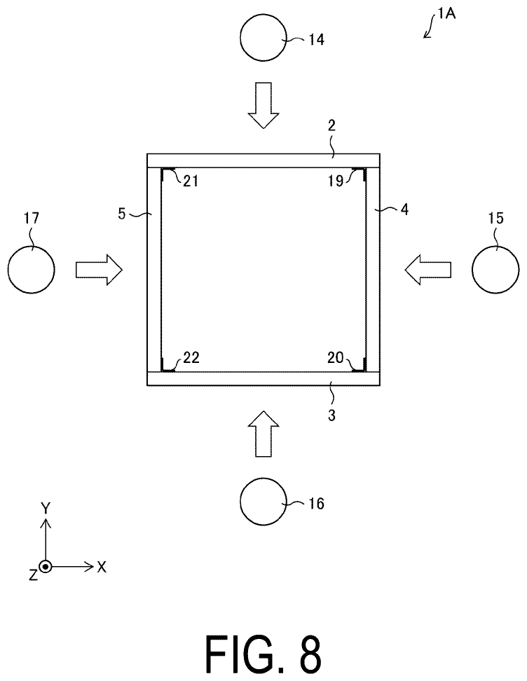

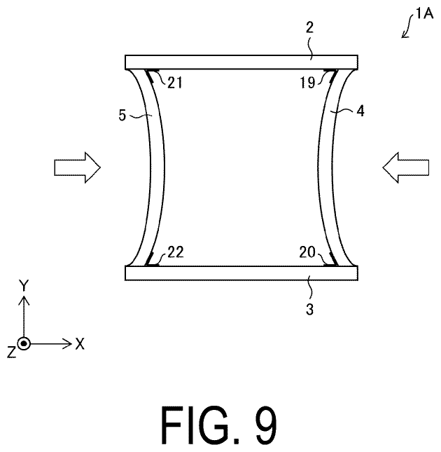

FIG. 7 is a perspective view of a multi-surface display device 1A according to a modified example. FIG. 8 is a plan view of the multi-surface display device 1A according to the modified example. FIG. 9 is a plan view illustrating a storage operation of the multi-surface display device 1A according to the modified example. Constituent elements similar to the constituent elements described above are denoted by the same reference numerals, and detailed descriptions thereof will not be repeated.

The multi-surface display device 1A may further include a hinge 19 (first hinge) for connecting the first display panel 2 and the third display panel 4 to each other, a hinge 20 (second hinge) for connecting the second display panel 3 and the third display panel 4 to each other, a hinge 21 (third hinge) for connecting the first display panel 2 and the fourth display panel 5 to each other, and a hinge 22 (fourth hinge) for connecting the second display panel 3 and the fourth display panel 5 to each other.

A plurality of hinges 19 to 22 may be provided at specific positions along a Z direction in a spot-like manner, or may be provided so as to extend along the Z direction.

Each of the hinges 19 to 22 preferably has a hinge-like structure. For example, the hinge 19 preferably includes, in the use state, one piece provided on the display panel 2 extending along the X direction and the other piece provided on the display panel 4 extending along the Y direction. The hinge 20 preferably includes one piece provided on the display panel 3 extending along the X direction and the other piece provided on the display panel 4 extending along the Y direction. The hinge 21 preferably includes one piece provided on the display panel 2 extending along the X direction and the other piece provided on the display panel 5 extending along the Y direction. The hinge 22 preferably includes one piece provided on the display panel 3 extending along the X direction and the other piece provided on the display panel 5 extending along the Y direction.

The hinges 19 to 22 may be made of a material such as glass fiber and having a shape memory function.

In the storage state of the multi-surface display device 1A arranged in the quadrangular shape, an operation can be achieved by the hinges 19 to 22 with high reliability in which the third display panel 4 and the fourth display panel 5 are folded so as to protrude inward, and the first display panel 2 and the second display panel 3 are closer to each other than in the use state.

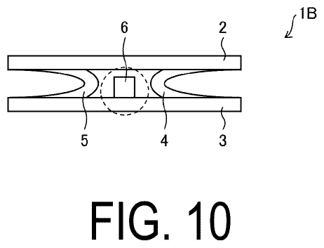

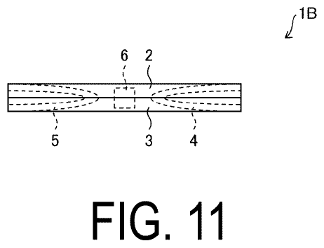

FIGS. 10 and 11 are plan views each illustrating a storage operation of a multi- surface display device 1B according to another modified example. Constituent elements similar to the constituent elements described above are denoted by the same reference numerals, and detailed descriptions thereof will not be repeated.

The multi-surface display device 1B further includes a circuit member 6 disposed on the second display panel 3 for displaying information on the first, second, third, and fourth display panels 2, 3, 4, and 5. The circuit member 6 is dispose at a position on the second display panel 3 away from the third display panel 4 and the fourth display panel 5 folded so as to be protrude inward in the storage state.

The circuit member 6 includes a power supply mechanism for supplying power to the first to fourth display panels 2 to 5 and an electronic circuit for displaying information on the first to fourth display panels 2 to 5.

Thus, the circuit member 6 for displaying information on the first to fourth display panels 2 to 5 is stored inside the multi-surface display device 1A in which the third display panel 4 and the fourth display panel 5 are folded to be in the storage state. Thus, the storage of the multi-surface display device 1A including the circuit member 6 can be further facilitated.

The example has been described in which the circuit member 6 is disposed on the second display panel 3. However, no such limitation is intended, and the circuit member 6 may be disposed on the first display panel 2.

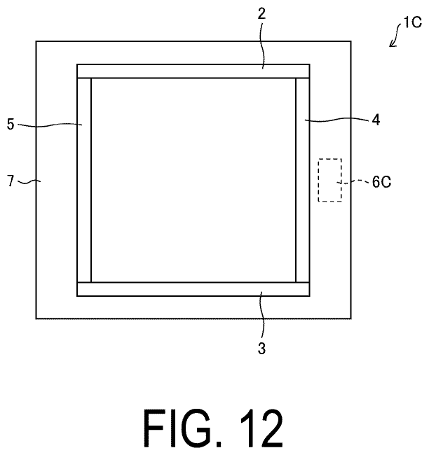

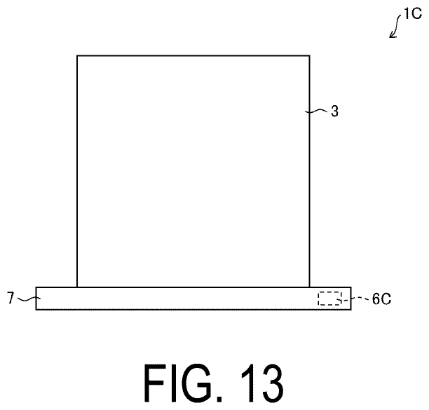

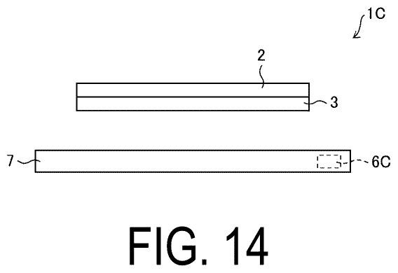

FIG. 12 is a plan view of a multi-surface display device 1C according to further another modified example. FIG. 13 is a front view of the multi-surface display device 1C. FIG. 14 is a plan view illustrating a storage operation of the multi-surface display device 1C. Constituent elements similar to the constituent elements described above are denoted by the same reference numerals, and detailed descriptions thereof will not be repeated.

The multi-surface display device 1C further includes a pedestal 7 on which the first, second, third, and fourth display panels 2, 3, 4, and 5 are placed and a circuit member 6C provided on the pedestal 7 for displaying information on the first, second, third, and fourth display panels 2, 3, 4, and 5.

All terminals and mechanisms necessary for displaying information on the first, second, third, and fourth display panels 2, 3, 4, and 5 are provided on the pedestal 7. The circuit member 6C is provided inside the pedestal 7. The first, second, third, and fourth display panels 2, 3, 4, and 5 are fitted to the terminals of the pedestal 7 and thus electrically connected to the circuit member 6C.

The storage state of the multi-surface display device 1C is in a two-part state of a storage panel unit having a compact size corresponding to two display panels and the pedestal 7.

Thus, by providing the circuit member 6C for displaying information on the first, second, third, and fourth display panels 2, 3, 4, and 5 on the pedestal 7, the use state in the flat plate shape of the third display panel 4 and the fourth display panel 5 and the storage state in which the third display panel 4 and the fourth display panel 5 are folded such that the first display panel 2 and the second display panel 3 are closer to each other than in the use state can be easily switched.

### Second Embodiment

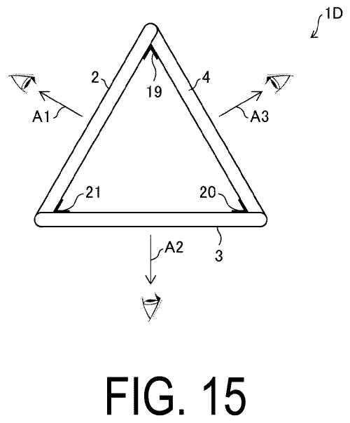

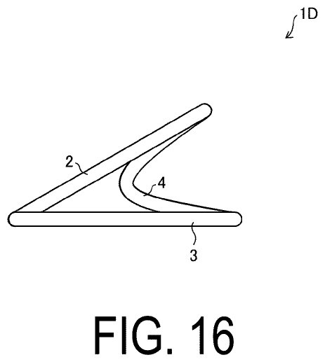

FIG. 15 is a plan view of a multi-surface display device 1D according to a second embodiment. FIG. 16 is a plan view illustrating a storage operation of the multi-surface display device 1D. Constituent elements similar to the constituent elements described above are denoted by the same reference numerals, and detailed descriptions thereof will not be repeated.

In the multi-surface display device 1D, the first display panel 2 and the second display panel 3 are connected to each other. In the use state illustrated in FIG. 15, the first, second, and third display panels 2, 3, and 4 are arranged in a triangular shape.

The multi-surface display device 1D includes the first display panel 2 that performs display toward an arrow Al direction (first direction), the second display panel 3 that performs display toward an arrow A2 direction (second direction), and the third display panel 4 that is foldable and connected to the first display panel 2 and the second display panel 3 to perform display toward an arrow A3 direction (third direction).

Third display panel 4 is switched between the use state in the flat plate shape illustrated in FIG. 15 and the storage state illustrated in FIG. 16 in which the third display panel 4 is folded such that the first display panel 2 and the second display panel 3 are closer to each other than in the use state illustrated in FIG. 15.

Thus, the multi-surface display device 1D having the triangular shape in the use state can be easily stored when not in use.

The examples have been described in which the multi-surface display device 1D has the quadrangular shape or the triangular shape in the use state. However, no such limitation is intended, and the multi-surface display device may be configured to have a polygonal shape such as a pentagonal shape or more in the use state, or an irregular shape in the use state.

### Third Embodiment

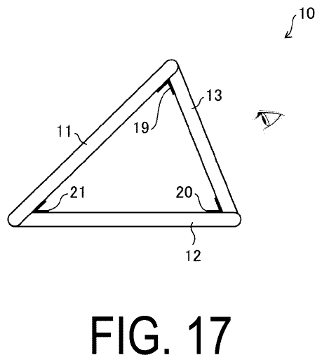

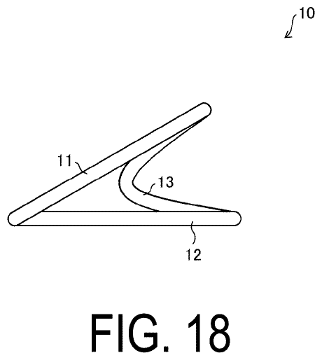

FIG. 17 is a schematic view of a display device 10 according to a third embodiment. FIG. 18 is a schematic view illustrating a storage operation of the display device 10. Constituent elements similar to the constituent elements described above are denoted by the same reference numerals, and detailed descriptions thereof will not be repeated.

The display device 10 includes a first plate-shaped member 11, a second plate- shaped member 12 connected to the first plate-shaped member 11, and a display panel 13 that is connected to the first plate-shaped member 11 and the second plate-shaped member 12 to be foldable. The display panel 13 is switched between the use state in the flat plate shape illustrated in FIG. 17 and the storage state illustrated in FIG. 18 in which the display panel 13 is folded such that the first plate-shaped member 11 and the second plate-shaped member 12 are closer to each other than in the use state.

The first plate-shaped member 11 may be a lid portion and the second plate-shaped member 12 may be a bottom portion. The example has been described in which the display panel 13 is folded so as to protrude inward. However, no such limitation is intended, and the display panel 13 may be bent so as to protrude outward.

Thus, the storage state when not in use of the display device 10 including the first plate-shaped member 11, the second plate-shaped member 12 connected to the first plate- shaped member 11, and the display panel 13 connected to the first plate-shaped member 11 and the second plate-shaped member 12 becomes more compact than in the use state. As a result, the storage when not in use of the display device 10 is facilitated.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1. A multi-surface display device comprising:
a first display panel configured to perform display toward a first direction;
a second display panel configured to perform display toward a second direction different from the first direction; and
a third display panel that is foldable and connected to the first display panel and the second display panel and configured to perform display toward a third direction different from the first and second directions,
wherein the third display panel is switched between a use state in a flat plate shape and a storage state in which the third display panel is folded, and the first display panel and the second display panel are closer to each other than in the use state.

2. The multi-surface display device according to claim 1, further comprising:
a fourth display panel that is foldable and connected to the first display panel and the second display panel and configured to perform display toward a fourth direction different from the first, second, and third directions,
wherein the fourth display panel has a flat plate shape in the use state, and in the stored state, is folded and the first display panel and the second display panel are closer to each other in the stored state than in the use state,
the first, second, third, and fourth display panels are arranged in a quadrangular shape in the use state, and
the third display panel and the fourth display panel are folded to protrude inward in the storage state.

3. The multi-surface display device according to claim 2,
wherein the first and second display panels are configured to be foldable,
the first, second, third, and fourth display panels are integrally formed,
in the use state, a portion between the first display panel and the third display panel is bent at a right angle, and a portion between the first display panel and the fourth display panel is bent at a right angle, and
in the storage state, the portion between the first display panel and the third display panel is bent at an acute angle, and the portion between the first display panel and the fourth display panel is bent at an acute angle.

4. The multi-surface display device according to claim 2, further comprising:
a first hinge configured to connect the first display panel and the third display panel to each other;
a second hinge configured to connect the second display panel and the third display panel to each other;
a third hinge configured to connect the first display panel and the fourth display panel to each other; and
a fourth hinge configured to connect the second display panel and the fourth display panel to each other.

5. The multi-surface display device according to claim 1,
wherein the first, second, and third display panels each include an organic light-emitting diode.

6. The multi-surface display device according to claim 2, further comprising:
a circuit member disposed on the first or second display panel and configured to display information on the first, second, third, and fourth display panels,
wherein the circuit member is disposed at a position on the first display panel or the second display panel away from the third display panel and the fourth display panel folded to protrude inward in the storage state.

7. The multi-surface display device according to claim 1, further comprising:
a pedestal on which the first, second, and third display panels are placed; and
a circuit member provided on the pedestal and configured to display information on the first, second, and third display panels.

8. The multi-surface display device according to claim 1,
wherein the first display panel and the second display panel are connected to each other, and
the first, second, and third display panels are arranged in a triangular shape in the use state.

9. The multi-surface display device according to claim 1,
wherein a metal thin plate having a mesh shape is attached to the third display panel.

10. (canceled)
